(19) United States
(12) Patent Application Publication
(10) Pub. No.: US 2016/0110102 A1
(43) Pub. Date: Apr. 21, 2016

(54) HYBRID MEMORY MODULE STRUCTURE AND METHOD OF DRIVING THE SAME

(71) Applicant: Samsung Electronics Co., Ltd., Suwon-si (KR)

(72) Inventor: Sang-Kil LEE, Seongnam-si (KR)

(21) Appl. No.: 14/740,221

(22) Filed: Jun. 15, 2015

(30) Foreign Application Priority Data
Oct. 20, 2014 (KR) 10-2014-0141815

(51) Int. Cl. G06F 3/06; G11C 7/10

(52) U.S. Cl. CPC G06F 3/061; G06F 3/0688; G06F 3/0655; G11C 7/1072; G06F 3/0685

(57) ABSTRACT

A hybrid memory module structure includes a channel for receiving data from and transmitting data to a device external to the hybrid memory module structure, a first memory module connected to the channel, and a second memory module connected to the channel. The first memory module includes at least a first memory and a second memory, the first memory being a working memory and the second memory being a storage memory. The second memory module includes at least a third memory and a fourth memory, the third memory being a working memory and the fourth memory being a storage memory. The channel includes a first data line commonly connected to the first memory and the second memory, and a second data line commonly connected to the third memory and the fourth memory.

This application claims priority from Korean Patent Application No. 10-2014-0141815 filed on Oct. 20, 2014 in the Korean Intellectual Property Office, the disclosure of which is incorporated herein by reference in its entirety.

### BACKGROUND

The present disclosure relates to a hybrid memory module structure and a method of driving the same.

A conventional dual inline memory module (DIMM) refers to a memory module having a number of dynamic random access memory (DRAM) modules mounted on opposite sides of a circuit board. The DIMM is typically used as a main memory of a computer. A DIMM may also refer to DIMM specifications that define the arrangement of pins or electrical characteristics of the module, according to certain industry standards.

Typically, a data bus width of a DIMM is two or more times that of a single inline memory module (SIMM).

The DIMM specifications have been standardized by the Joint Electron Device Engineering Council (JEDEC) and vary according to the type of a synchronous dynamic random access memory (SDRAM) module mounted.

A DIMM interface typically consists of an address, data, and a control signal. Generally, a DIMM for 64-bit data is used in personal computers (PC), but a DIMM for 72-bit data including an 8-bit error correction code, is sometimes used in servers that require reliability.

The DIMM may be broadly classified into three types: an unbuffered DIMM, a buffered (registered) DIMM, and a fully buffered DIMM (FBDIMM). The DIMM can further be classified according to SDRAM specifications. Different types of DIMMs are generally incompatible with each other due to different access timings and interfaces. For systems including a number of DIMMs, there tends to be a design trade-off relationship between an actual transfer rate and the number of modules that can be mounted.

### SUMMARY

According to certain embodiments, a hybrid memory module structure includes: a channel for receiving data from and transmitting data to a device external to the hybrid memory module structure, and a first memory module connected to the channel. The first memory module including at least a first memory and a second memory, the first memory being a working memory and the second memory being a storage memory. A second memory module may also be connected to the channel, the second memory module including at least a third memory and a fourth memory, the third memory being a working memory and the fourth memory being a storage memory. The channel may include a first data line commonly connected to the first memory and the second memory, and a second data line commonly connected to the third memory and the fourth memory.

In one embodiment, the first memory and third memory are the same type of memory, and the second memory and fourth memory are the same type of memory.

For example, the first memory and third memory may be volatile memories, and the second memory and fourth memory may be nonvolatile memories.

In one embodiment, the first memory and third memory are dynamic random access memories (DRAMs), and the second memory and fourth memory are one of: flash memory, phase change random access memory (PRAM), resistance random access memory (RRAM), nano-floating gate memory (NFGM), polymer random access memory (PoRAM), magnetic random access memory (MRAM), and ferroelectric random access memory (FRAM).

In certain embodiments, the first data line is not connected to the third or fourth memories, and the second data line is not connected to the first or second memories.

In one embodiment, the first memory module further comprises a controller which allocates serial data received from a host through the first data line to the second memory and allocates non-serial data to the first memory.

In one embodiment, the first memory module further comprises a controller configured to classify data received from a host through the first data line and perform read and write operations on behalf of the first and second memories. The controller may be configured to classify the data based on a marking of the data made by the host, or based on a transmission mode of the data.

In certain embodiments, each memory of the first memory module includes one or more semiconductor chips, and each memory of the second memory module includes one or more semiconductor chips.

The first memory module may be a dual inline memory module including at least four memories that include the first memory and second memory, and the second memory module may be a dual inline memory module including at least four memories that include the third memory and fourth memory.

Read and write operations of the first memory may be faster than those of the second memory.

Further, in certain embodiments, the channel may include two slots, a first for connecting the first memory module, and a second for connecting the second memory module.

According to certain aspects of the disclosed embodiments, a hybrid memory module structure includes: a channel for receiving data from and transmitting data to a device external to the hybrid memory module; a first hybrid memory module connected to the channel, the first hybrid memory module including at least a first memory and a second memory, the first memory being a different type of memory from the second memory; a second hybrid memory module connected to the channel, the second memory module including at least a third memory and a fourth memory, the third memory being a different type of memory from the fourth memory; a first data line of the channel commonly connected to the first memory and the second memory and not connected to the third memory or the fourth memory; and a second data line of the channel commonly connected to the third memory and the fourth memory and not connected to the first memory or the second memory.

The first data line may be connected to a first slot to which the first hybrid memory module connects, and the second data line may be connected to a second slot to which the second hybrid memory module connects.

In certain embodiments, the first and third memories are working memories, and the second and fourth memories are storage memories.

For example, the first memory and third memory may be volatile or nonvolatile memories, and/or the second memory and fourth memory may be nonvolatile memories.

In one embodiment, the hybrid memory module structure further includes a first controller on the first hybrid memory module, the first controller configured to receive data from the first data line and to determine which of the first or second memories in which to store the received data; and a second memory controller on the second hybrid memory module, the second memory controller configured to receive data from the second data line and to determine which of the third or fourth memories in which to store the received data.

According to further aspects of the disclosed embodiments, a hybrid memory module structure includes: a channel for receiving data from and transmitting data to a device external to the hybrid memory module; a first hybrid memory module connected to the channel, the first hybrid memory module including at least a first memory and a second memory, the first memory being a different type of memory from the second memory; a second hybrid memory module connected to the channel, the second memory module including at least a third memory and a fourth memory, the third memory being a different type of memory from the fourth memory; a first controller on the first hybrid memory module, the first controller configured to receive data from the channel and to determine which of the first or second memories in which to store the received data; and a second memory controller on the second hybrid memory module, the second memory controller configured to receive data from the channel and to determine which of the third or fourth memories in which to store the received data.

The hybrid memory module structure may additionally include: a first data line of the channel commonly connected to the first memory and the second memory through the first controller; and a second data line of the channel commonly connected to the third memory and the fourth memory through the second memory controller.

According to yet another aspect of the disclosed embodiments, an electronic device includes: a first memory controller; a first data line connected to the first memory controller and for communicating with an external host; and a first hybrid memory module connected to the first memory controller, the first hybrid memory module including at least a first memory and a second memory, the first memory being a first type of memory and the second memory being a second type of memory. The first memory controller is configured to determine whether data received from the host is to be allocated to the first memory or the second memory.

The first type of memory may be a working memory, and the second type of memory may be a storage memory.

In one embodiment, the first memory controller is configured to classify the data based on a marking of the data made by the host, or based on a transmission mode of the data, in order to make the determination.

The electronic device may further include: a second memory controller; a second data line connected to the second memory controller and for communicating with the external host; and a second hybrid memory module connected to the second memory controller, the second hybrid memory module including at least a first memory and a second memory, the first memory of the second hybrid memory module being the first type of memory and the second memory of the second hybrid memory module being the second type of memory. The second memory controller may be configured to determine whether data received from the host is to be allocated to the first memory of the second hybrid memory module or the second memory of the second hybrid memory module.

In one embodiment, the first data line and the second data line are part of a single channel connected to the first hybrid memory module and the second hybrid memory module.

The first hybrid memory module may have a DIMM structure, and the second hybrid memory module may have a DIMM structure.

In one embodiment, the first type of memory has a faster access time than the second type of memory. For example, the first memory may be a DRAM, and the second memory may be a one of: flash memory, phase change random access memory (PRAM), resistance random access memory (RRAM), nano-floating gate memory (NFGM), polymer random access memory (PoRAM), magnetic random access memory (MRAM), and ferroelectric random access memory (FRAM).

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a conceptual diagram of a computing device including a hybrid dual inline memory module (DIMM) structure according to a first exemplary embodiment of the present inventive concept;

FIG. 2 is a block diagram illustrating an exemplary structure of the hybrid DIMM structure according to the first embodiment of the present inventive concept;

FIG. 3 is a conceptual diagram of a conventional hybrid DIMM structure;

FIG. 4 is a block diagram illustrating an exemplary structure of the hybrid DIMM structure according to the first exemplary embodiment of the present inventive concept;

FIG. 5 is a block diagram illustrating an exemplary internal structure of the hybrid DIMM structure according to the first exemplary embodiment of the present inventive concept;

FIG. 6 is a block diagram illustrating an exemplary internal structure of a hybrid DIMM structure according to a second exemplary embodiment of the present inventive concept;

FIG. 7 is a table comparing exemplary first and second memories of the hybrid DIMM structure according to the second exemplary embodiment of the present inventive concept;

FIG. 8 is a flowchart illustrating an exemplary method of driving the hybrid DIMM structure according to the first exemplary embodiment of the present inventive concept;

FIG. 9 is a flowchart illustrating, in greater detail, an exemplary method of driving the hybrid DIMM structure according to the first exemplary embodiment of the present inventive concept;

FIG. 10 is a flowchart illustrating another exemplary method of driving the hybrid DIMM structure according to the first exemplary embodiment of the present inventive concept; and

FIG. 11 is a flowchart illustrating an exemplary method of driving the hybrid DIMM structure according to the second exemplary embodiment of the present inventive concept.

### DETAILED DESCRIPTION

Advantages and features of the present inventive concept and methods of accomplishing the same may be understood more readily by reference to the following detailed description of exemplary embodiments and the accompanying drawings. The present inventive concept may, however, be embodied in many different forms and should not be construed as being limited to the embodiments set forth herein. These exemplary embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention. Like reference numerals refer to like elements throughout the specification.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another region, layer or section. Thus, a first element, component, region, layer or section discussed in one part of the specification could be termed a second element, component, region, layer or section in another part of the specification without departing from the teachings of the present inventive concept. In addition, in certain cases, even if a term is not described using “first,” “second,” etc., in the specification, it may still be referred to as “first” or “second” in a claim in order to distinguish different claimed elements from each other.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

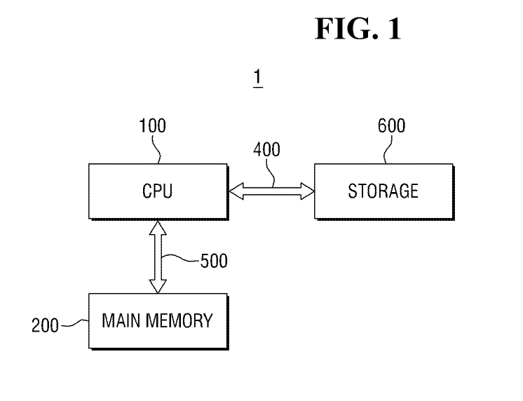

A hybrid dual memory module structure according to a first, exemplary embodiment of the present inventive concept will now be described with reference to FIGS. 1 through 5.

FIG. 1 is a conceptual diagram of a computing device, generally described herein as an electronic device, including a hybrid DIMM structure 1 according to a first exemplary embodiment of the present inventive concept. Although a hybrid DIMM structure is shown in FIG. 1 and specifically described in connection with certain embodiments herein, aspects of the disclosure may be applied to a hybrid memory module structure that is not a DIMM.

Referring to FIG. 1, the computing device including the hybrid DIMM structure 1 according to one embodiment includes a central processing unit (CPU) 100, a main memory 200, a storage device 600, a storage interface 400, and a memory bus 500.

The CPU 100 may be a device that interprets commands of the computing device and executes arithmetic and logic operations or data processing. The CPU 100 may include, for example, a program counter, an arithmetic and logic unit (ALU), various registers, a command interpretation unit, a control unit, and a timing generation circuit.

The CPU 100 may include a single processor core or multiple processor cores in order to process data. In one example, the CPU 100 may include a multi-core such as a dual-core, a quad-core, or a hexa-core. The CPU 100 may further include a cache memory. The cache memory may be positioned inside the CPU 100. Alternatively, a cache memory for the CPU 100 may be positioned outside the CPU 100.

The main memory 200 may be used to store data processed by the CPU 100 or may function as a working memory of the CPU 100.

In an example, the main memory 200 may be a dynamic random access memory (DRAM) such as a double data rate synchronous dynamic random access memory (DDR SDRAM), a lower power double data rate (LPDDR) SDRAM, a graphics double data rate (GDDR) SDRAM or a Rambus DRAM (RDRAM). Alternatively, the main memory 200 may be another type of volatile memory that requires a refresh operation. Thus, the main memory 200 may be a memory that loses stored data when power supply is interrupted. In other embodiments, however, the main memory 200 may include non-volatile memory, such as a magnetic random access memory (MRAM) that may be controlled in the same or similar manner as a DRAM.

The main memory 200 may be fabricated using a semiconductor device, such as one or more semiconductor memory chips or packages. The processing speed of the main memory 200 may he higher than that of the storage device 600. For example, the latency of read and write accesses may be less for the main memory 200 than for the storage device 600.

The storage device 600 may exist outside the CPU 100. The storage device 600 may be used as an auxiliary memory to supplement the limited memory capacity of the main memory 200. In one embodiment, the storage device 600 does not lose stored data even when a power supply is interrupted. Thus, the storage device 600 may be a nonvolatile memory.

The storage device 600 may be relatively slower than the main memory 200. However, in certain embodiments, the storage device 600 can store a large amount of data semi-permanently.

The storage device 600 may use a magnetic tape or a magnetic disk. In certain embodiments, the storage device 600 may access data using a sequential access method and a direct access method.

In one example of the sequential access method, information is read and written only sequentially. Therefore, the sequential access method may provide good recording density but may require a lot of time for information retrieval. in addition, the sequential access method may require reconfiguration for data insertion and deletion. A magnetic tape uses the sequential access method.

In the direct access method, information is read and written sequentially or directly at a necessary location. A magnetic drum and a magnetic disk use the direct access method. Thus, the magnetic drum and the magnetic disk are referred to as direct access storage devices (DASDs).

The storage device 600 may also use a semiconductor type memory. The storage device 600 using a magnetic disk is referred to as a hard disk drive (HDD). There has been a relatively rapid improvement in the operating speeds of the CPU 100 and the main memory 200. However, the improvement in the operating speed of the HDD has been relatively slow. Therefore, a solid state drive (SSD) using a semiconductor instead of a magnetic disk can be used as the storage device 600.

The SSD may include an interface (such as a connection port) and a data storage memory, which are connected to the CPU 100, a controller, which controls data exchange between the interface and the memory, and a buffer memory, which may compensate for the differences in speed between an external device and the SSD.

The data storage memory may function as a typical random access memory (RAM). The speed of a RAM-based SSD may be very high. However, since the RAM in this case is a volatile memory that loses all its stored data When the power is turned off, the RAM-based SSD may include a dedicated battery that continuously supplies power to the SSD even after the power is turned off.

However, when the battery is discharged, all data in the RAM-based SSD may disappear. Therefore, an SSD using a flash memory instead of the RAM may be utilized for the sake of safety.

The flash memory is a nonvolatile memory that retains recorded data even when power supply is interrupted. Therefore, the flash memory can be used like a conventional HDD. The SSD loaded with the flash memory may be relatively slower than the SSD loaded with the RAM but may be far faster than the HDD.

The flash memory may be classified into two types: a NAND flash memory which is typically used for data storage and has a large storage capacity and a NOR flash memory which is typically used for code storage and has a high processing speed. The NAND flash memory may mostly be used in an SSD for data storage.

The storage interface 400 may connect the CPU 100 and the storage device 600. The storage interface 400 may serve as a path for data exchange between the CPU 100 and the storage device 600. In the storage interface 400, data may move in both directions.

The storage interface 400 may be, but is not limited to, parallel advanced technology (AT) attachment (PATA), small computer system interface (SCSI), serial AT attachment (SATA), serial attached SCSI (SAS), or peripheral component interconnect-express (PCI-e).

The memory bus 500 may connect the CPU 100 and the main memory 200. The memory bus 500 may serve as a path for data exchange between the CPU 100 and the main memory 200. In the memory bus 500, data may move in both directions. That is, the memory bus 500 may be a two-way (i.e., bi-directional) bus.

The memory bus 500 may transmit data in parallel. For example, in the case of 64 bits, eight data lines may each transmit 8 bits of data simultaneously. A single data line may transfer 64 bits and a line within the data line may transfer 8 bits; a data line in this example therefore comprises 8 lines (64 bits). Each of those lines may transfer 1 bit. However, the present inventive concept is not limited thereto. As used in the specification, the term “line” or “data line” may refer to a single signal line that transfers one signal, which may represent for example one bit of information, or may refer to a set of lines (e.g., 8 lines) including a plurality of such single signal lines, or a group of sets of lines (e.g., eight 8-line sets that form a 64-bit data line).

As described herein, a main memory, such as main memory 200, when discussed in connection with embodiments of the invention, may refer functionally to a memory that operates as a working memory, even though it may include memory devices on different memory modules. Similarly, a storage, such as storage 600, when discussed in connection with embodiments of the invention, may refer functionally to a memory that operates as a storage memory, even though it may include memory devices on different memory modules.

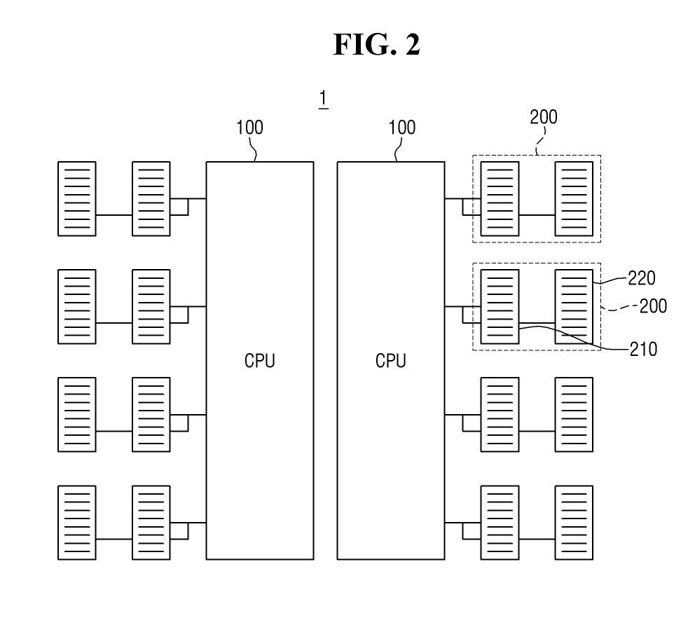

FIG. 2 is a block diagram illustrating an exemplary structure of the hybrid DIMM structure 1 according to the first exemplary embodiment of the present inventive concept.

Referring to FIG. 2, the hybrid DIMM structure 1 according to one embodiment may have a DIMM structure.

In this DIMM structure, a plurality of memory module structures 200 may be connected to the CPU 100 by a plurality of channels. For example, one memory module structure 200 is connected to the CPU 100 by one channel, and the number of channels is equal to the number of the memory module structures 200.

One first memory module structure 200 may have a plurality of slots. In FIG. 2, each first memory module structure 200 has two slots, and a first memory module (e.g., DIMM) 210 and a second memory module (e.g., DIMM) 220 are installed in the two slots, respectively.

The two slots are merely an example, and the number of slots is not limited to two. In certain embodiments, the number of slots is any number greater than one. For example, the number of slots can be three or four, or a larger number.

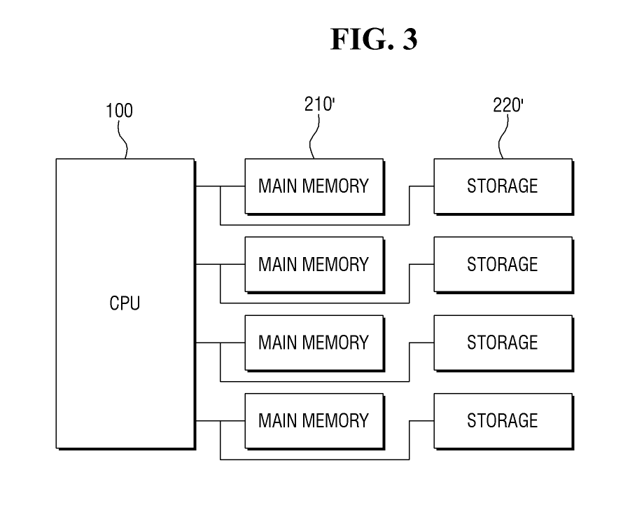

FIG. 3 is a conceptual diagram of a conventional DIMM structure.

In a conventional DIMM structure, a storage device may communicate with a CPU through a storage interface. The storage interface may be relatively slower than an interface of the main memory.

Therefore, using empty slots of the DIMM structure can be considered in order to increase a data transfer rate between the storage device and the CPU.

Specifically, a CPU may have a plurality of channels. For example, the CPU 100 may have a plurality of channels, each connected to a main memory 210′ which is a DRAM. The main memories 210′ may comprise a plurality of modules, and the modules may correspond respectively to the channels. Therefore, the modules may transmit or receive data to or from the CPU 100 using different memory buses.

As such, the main memories 210′ of different channels may transmit or receive data to or from the CPU 100 using different memory buses. However, a memory bus belonging to one channel may be connected to an additional storage device 220′. For example, a main memory 210′ and a storage device 220′ may share a memory bus that forms one channel.

In this structure, since the storage device 220′ utilizes the existing memory interface, it can operate at far higher speed.

However, using empty slots as described above can reduce the performance of the main memories 210′. For example, based on testing of certain DIMMs, it was found that if a main memory 210′ and a storage device 220′ are respectively installed in two slots of one channel, the performance of the main memory 210′ may be reduced by as much as 19%. For example a speed of the main memory 210′ may decrease by up to 19%.

This occurs because the operation of the main memory 210′ is hindered as the storage device 220′ operates while occupying the channel. When only one slot is used, the main memory 210′ can monopolize a memory bus. However, when the storage device 220′ is installed in a second slot, the main memory 210′ and the storage device 220′ should share one memory bus. Therefore, the speed or performance of the main memory 210′ can be reduced.

Further, if an empty slot of each channel is additionally filled, a performance reduction may be caused by DIMM loading. For example, when a DIMM is installed in one DIMM slot of each channel, one additional DIMM of the same type may be added to each channel. Therefore, two DIMMs may respectively be installed in two DIMM slots of each channel, which has been shown to result in a performance reduction (e.g., decreased speed) of approximately 6%. In addition, when DIMMs are installed in two slots of each channel, one additional DIMM may be added to each channel. Therefore, three DIMMs may respectively be installed in three DIMM slots of each channel, resulting in a performance reduction of approximately another 6%. That is, the addition of each DIMM to each channel may result in a performance reduction of approximately 6%.

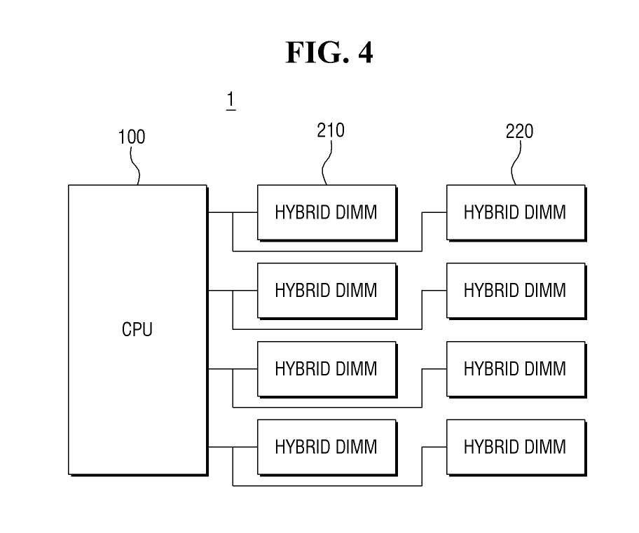

FIG. 4 is a block diagram illustrating the structure of a hybrid memory module structure, such as a hybrid DIMM structure 1 according to the first embodiment of the present inventive concept.

Referring to FIG. 4, the hybrid DIMM structure 1 according to the first embodiment of the present inventive concept includes the CPU 100, the first DIMMs 210, and the second DIMMs 220.

The hybrid DIMM structure 1 according to the first embodiment may use two slots. However, contrary to the conventional structure that uses a main memory 210′, such as a first type of memory, (see FIG. 3) installed in a first slot of each channel, and a storage device 220′, such as a second type of memory (see FIG. 3) installed in a second slot of each channel, the hybrid DIMM structure 1 according to the first embodiment includes identical hybrid memory modules, such as hybrid DIMMs (210 and 220) in the first and second slots. For example, the first and second DIMMs 210 and 220 may have the same configuration. However, the present inventive concept is not limited thereto. Still, according to various embodiments, each hybrid memory module connected to the same channel includes both a main memory, also described herein as a working memory as it typically stores data for applications and other processes that are running, and a storage memory, which may store data intended to be stored beyond the current operating time of any particular application.

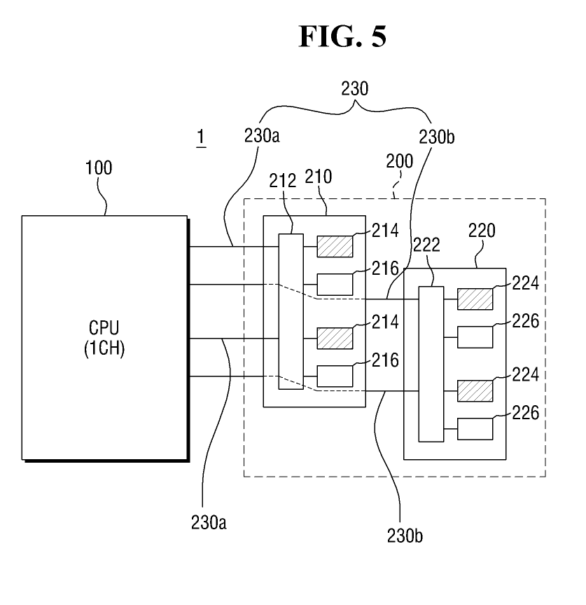

The hybrid DIMM structure 1 according to the first embodiment will now be described in detail with reference to FIG. 5.

FIG. 5 is a block diagram illustrating an exemplary internal structure of a hybrid DIMM structure 1 according to the first embodiment of the present inventive concept. Though a DIMM structure is described, the principles described herein may be applied any hybrid memory module, or for any memory module structure that permits two memory modules to be connected to a single channel, for example, via two slots, where each of the two memory modules includes different types of memory. In FIG. 5, only one channel among a plurality of channels connected to the CPU 100 of FIG. 1 is illustrated.

Referring to FIG. 5, the hybrid DIMM structure 1 according to the first embodiment of the present inventive concept includes the CPU 100, a data line 230, and a first memory module structure 200.

The CPU 100 may transmit or receive data to or from the first memory module 200. For example, the CPU 100 can transmit data to the first memory module 200 through the data line 230. The performance of the CPU 100 may correspond to the performance of the data line 230. For example, if the CPU 100 operates at 64 bits for a certain period of time, the data line 230 may transmit 64 bits for the certain period of time. However, the present inventive concept is not limited thereto.

The data line 230 may denote a memory bus. The data line 230 may include a plurality of lines. For example, the data line 230 may include eight lines. In one embodiment, if the data line 230 transmits 64 bits for a certain period of time, the eight lines may each transmit 8 bits simultaneously.

The data line 230 may include a first data line 230a and a second data line 230b. The first data line 230a may include some of the lines included in the data line 230, and the second data line 230b may include the other ones of the lines. For example, the data line 230 may be halved into the first data line 230a and the second data line 230b.

In certain embodiments, the first data line 230a and the second data line 230b can transmit the same amount of data for the same period of time. For example, the first data line 230a and the second data line 230b can halve the data line 230. However, the present inventive concept is not limited thereto. For example, when the number of memory modules connected to the channel is not two, the data line 230 can be divided into a number of data lines equal to the number of memory modules connected to the channel.

The first memory module structure 200 may include a first memory module 210 and a second memory module 220. In one example, as described below, each of the first memory module 210 and the second memory module 220 is a DIMM.

In one embodiment, the first DIMM 210 may be connected to the first data line 230a and may not be connected to the second data line 230b. Therefore, the first DIMM 210 may be connected to a part of the data line 230 and may not be connected to the other part of the data line 230. Thus, a first group of lines that include a plurality of sets of data lines (e.g., four sets of 8-bit data lines) may connect to the first memory module 210.

The first DIMM 210 may include a first memory controller 212, first memories 214, and second memories 216. In one embodiment, the first memories 214 may be a first type of memory, such as volatile memories. For example, the first memories 214 may be, e.g., DRAMs. However, the present inventive concept is not limited thereto, and other volatile memories, or nonvolatile memories, can be used.

Each of the first memories 214 can operate as a main memory, or working memory. Consequently, the first memories 214 of the first DIMM 210 can exchange data with the CPU 100 using the first data line 230a, which is a part of the data line 230.

Each of the first memories 214 may include one or more semiconductor memory devices. For example, each memory 214 may be a semiconductor memory package that includes one or more semiconductor chips. Further, each memory 214 may include a plurality of packages that form a package-on-package device.

In one embodiment, the second memories 216 may be a second type of memory, such as nonvolatile memories. For example, in one embodiment, each of the second memories 216 may be part of an SSD, such as a NAND flash memory. However, the present inventive concept is not limited thereto, and other types of nonvolatile memories, such as PRAM, an RRAM, an NFGM, a PoRAM, an MRAM, and an FRAM, may be used, for example. Each of the second memories 216 may be a memory that can serve as the storage device 600, and thus may be referred to as a storage memory.

As such, each of the second memories 216 can operate as the storage device 600. In one embodiment, the second memories 216 of the first DIMM 210 can exchange data with the CPU 100 using the first data line 230a, which is a part of the data line 230.

Each of the second memories 216 may include one or more semiconductor memory devices. For example, each memory 216 may be a semiconductor memory package that includes one or more semiconductor chips. Further, each memory 216 may include a plurality of packages that form a package-on-package device.

The first memory controller 212 may control data of the first memories 214 and the second memories 216. For example, the first memory controller 212 may receive data from the CPU 100 and classify the received data. In one embodiment, the first memory controller 212 may determine to which of the first and second memories 214 and 216 the received data will be allocated.

Data allocated to the first memories 214 may be data used for the operation of main memories. Data allocated to the second memories 216 may be data to be stored in storage devices. For example, the data allocated to the first memories 214 may be data retained while power is supplied for operations. On the other hand, the data allocated to the second memories 216 may be data stored in nonvolatile memories, that is, data retained even after the power supply is interrupted. Or, described in another way, data allocated to the first memories 214 may be working data, that is associated with applications that are currently in progress and/or being used, while data allocated to the second memories 216 may be storage data, to remain in storage after an application is no longer in use or after a device's power is shut down.

The first memory controller 212 may determine where data should be allocated in various ways. For example, the first memory controller 212 may determine where data should be allocated based on a transmission mode of the data. For example, in one embodiment, data received continuously and sequentially (i.e., sequential data) may be stored in the second memories 216. For example, data stored in the second memories 216 may be mass data that should be retained even after power supply is interrupted.

Conversely, data received discontinuously and randomly may be considered as data to be stored temporarily for operations. Therefore, the randomly received data may be transmitted to the first memories 214.

The first memory controller 212 can also classify data using another method. A host, i.e., the CPU 100 transmits data to the first memory controller 212. In one embodiment, the CPU 100 may classify data to be transmitted and mark the data in advance. For example, the CPU 100 may mark whether the data should be allocated to a main memory or a storage device.

The first memory controller 212 may check the marking of the data and classify the data based on the marking. The first memory controller 212 may allocate data to the first and second memories 214 and 216 through this marking-based classification.

In certain embodiments, the first memory controller 212 may perform a buffer operation in order to adjust the difference in speed between the CPU 100 and the first memories 214. The first memory controller 212 may perform read and write operations on behalf of the first memories 214 and the second memories 216.

The second DIMM 220 may be connected to the second data line 230b and may not be connected to the first data line 230a, and thus may connect to the channel of the CPU 100 via the second data line 230b. As such, the second DIMM 220 may be connected to a part of the data line 230 and may not be connected to the other part of the data line 230.

The second DIMM 220 may include a second memory controller 222, third memories 224, and fourth memories 226. In one embodiment, the third memories 224 may be a third type of memory, such as volatile memories. The third type of memory may be the same as the first type of memory in the first DIMM 210. For example, the third memories 224 may be, e.g., DRAMs. However, the present inventive concept is not limited thereto, and other volatile memories, or nonvolatile memories, can be used. The third memories 224 may be of the same type as the first memories 214, or may be different types. The third memories 224 may be in the same category, or type, of memory as the first memories 214 (e.g., nonvolatile), and then may have the same or different types within that category, or sub-types within the type (e.g., both may be DRAM).

Each of the third memories 224 can operate as a main memory, or working memory. Consequently, the third memories 224 of the second DIMM 220 can exchange data with the CPU 100 using the second data line 230b, which is a part of the data line 230.

Each of the third memories 224 may include one or more semiconductor memory devices. For example, each memory 224 may be a semiconductor memory package that includes one or more semiconductor chips. Further, each memory 224 may include a plurality of packages that form a package-on-package device.

In one embodiment, the fourth memories 226 may be a second type of memory, such as nonvolatile memories. For example, in one embodiment, each of the fourth memories 226 may be part of an SSD, such as a NAND flash memory. However, the present inventive concept is not limited thereto. Other types of nonvolatile memories, such as PRAM, an RRAM, an NFGM, a PoRAM, an MRAM, and an FRAM, may be used, for example. Each of the fourth memories 226 may also be a memory that can serve as the storage device 600, and thus may be referred to as a storage memory. In one embodiment, the fourth memories 226 may be of the same type as the second memories 216, or may be different types. The fourth memories 226 may be in the same category, or type, of memory as the first memories 216 (e.g., nonvolatile), and then may have the same or different types within that category, or sub-types within the type (e.g., both may be NAND flash).

As such, each of the fourth memories 226 can operate as the storage device 600. In one embodiment, the fourth memories 226 of the second DIMM 220 can exchange data with the CPU 100 using the second data line 230b, which is a part of the data line 230.

Each of the fourth memories 226 may include one or more semiconductor memory devices. For example, each memory 226 may be a semiconductor memory package that includes one or more semiconductor chips. Further, each memory 226 may include a plurality of packages that form a package-on-package device.

The second memory controller 222 may control data of the third memories 224 and the fourth memories 226. For example, the second memory controller 222 may receive data from the CPU 100 and classify the received data. In one embodiment, the second memory controller 222 may determine to which of the third and fourth memories 224 and 226 the received data will be allocated.

Data allocated to the third memories 224 may be data used for the operation of main memories. Data allocated to the fourth memories 226 may be data to be stored in storage devices. For example, the data allocated to the third memories 224 may be data retained while power is supplied for operations. On the other hand, the data allocated to the fourth memories 226 may be data stored in nonvolatile memories, that is, data retained even after the power supply is interrupted. Or, described in another way, data allocated to the third memories 224 may be working data, that is associated with applications that are currently in progress and/or being used, while data allocated to the fourth memories 226 may be storage data, to remain in storage after an application is no longer in use or after a device's power is shut down.

The second memory controller 222 may determine to where data should be allocated in various ways. For example, the second memory controller 222 may determine to where data should be allocated based on the transmission mode of the data.

For example, in one embodiment, data received continuously and sequentially (i.e., sequential data) may be stored in the fourth memories 226. For example, data stored in the fourth memories 226 may be mass data that should be retained even after power supply is interrupted.

Conversely, data received discontinuously and randomly may be considered as data to be stored temporarily for operations. Therefore, the randomly received data may be transmitted to the third memories 224.

The second memory controller 222 can also classify data using another method. A host, i.e., the CPU 100 transmits data to the second memory controller 222. In one embodiment, the CPU 100 may classify data to be transmitted and mark the data in advance. For example, the CPU 100 may mark whether the data should be allocated to a main memory or a storage device.

The second memory controller 222 may check the marking of the data and classify the data based on the marking. The second memory controller 222 may allocate data to the third and fourth memories 224 and 226 through this marking-based classification.

In certain embodiments, the second memory controller 222 may perform a buffer operation in order to adjust the difference in speed between the CPU 100 and the third memories 224. The second memory controller 222 may perform read and write operations on behalf of the third memories 224 and the fourth memories 226.

In certain embodiments, the first and third memories 214 and 224 may be of the same type. For example, the first and third memories 214 and 224 may be volatile memories. For example, the first and third memories 214 and 224 may include DRAMs.

In certain embodiments, the second and fourth memories 216 and 226 may be of the same type. For example, the second and fourth memories 216 and 226 may be nonvolatile memories. For example, the second and fourth memories 216 and 226 may include devices that form SSDs. In particular, the second and fourth memories 216 and 226 may include NAND flash memories.

In certain embodiments, the first DIMM 210 and the second DIMM 220 may have the same configuration. However, the first DIMM 210 and the second DIMM 220 may use different parts of the data line 230. For example, the first DIMM 210 may use the first data line 230a, and the second DIMM 220 may use the second data line 230b.

Unlike in the conventional DIMM structure filling empty slots with different memory modules, in the hybrid DIMM structure 1 according to the first embodiment of the present inventive concept, DIMMs do not share the entire data line 230. Rather, the DIMMs described above use different parts of the data line 230, and the different parts may be dedicated the different respective DIMMs.

As a comparison, in the conventional DIMM structure filling empty slots, the main memory 210′ (see FIG. 3) and the storage device 220′ exist in different DIMMs. Accordingly, the performance of the main memory 210′ is reduced.

On the other hand, in the hybrid DIMM structure 1 according to the first embodiment of the present inventive concept, DIMMs use different parts of the data line 230 instead of sharing the data line 230. Therefore, although two DIMMs are used in the first memory module structure 200, the level of performance that can be obtained when only DIMM is used can be obtained because the two DIMMs use different parts of the data line 230 instead of sharing the data line 230. Although the data line 230 may be halved into the first data line 230a and the second data line 230b, such that each memory module 210 and 220 is connected to half of the number of lines as in the conventional DIMM structure, two simultaneous transfers may take place (e.g. one in each of the first data line 230a and second data line 230b), effectively and substantially operating at the same performance as compared to operations using the conventional DIMM. Thus, an added benefit in the hybrid DIMM structure 1 is to be able to perform storage operations without degrading the speed or size of the main memory accesses.

For example, if the first memory module of one channel consists of eight 8 GB first memories 214, all of the eight first memories 214 are included in the first DIMM 210 in the conventional DIMM structure. In the hybrid DIMM structure 1 according to the current embodiment, however, the eight first memories 214 are divided into two groups of four first memories 214, and four first memories 214 are included in each of the first DIMM 210 and the second DIMM 220. Therefore, the total number of the first memories 214 used is the same as in the conventional DIMM structure, and different parts of the data line 230 are used. Accordingly, the performance of the first memory module 210 may not be reduced. The performance of the first memory module 210 in the hybrid DIMM structure 1 when both slots are full may therefore be substantially the same as compared to performance of the conventional DIMM structure when one slot is empty.

In addition, since each of the first DIMM 210 and the second DIMM 220 has an empty space for accommodating eight memories, the second memories 216 can be added to this empty space. Therefore, the empty space can be utilized while the performance of the first memory module structure 200 is maintained by avoiding sharing the data line 230 between two different memory modules. Further, since the storage device 600 additionally uses a high-speed DIMM interface, far faster read and write operations are possible. The hybrid DIMM structure 1 according to the first embodiment of the present inventive concept converts data line sharing between DIMMs into data line sharing between heterogeneous memories within a DIMM. This fosters more efficient and faster memory and storage performance.

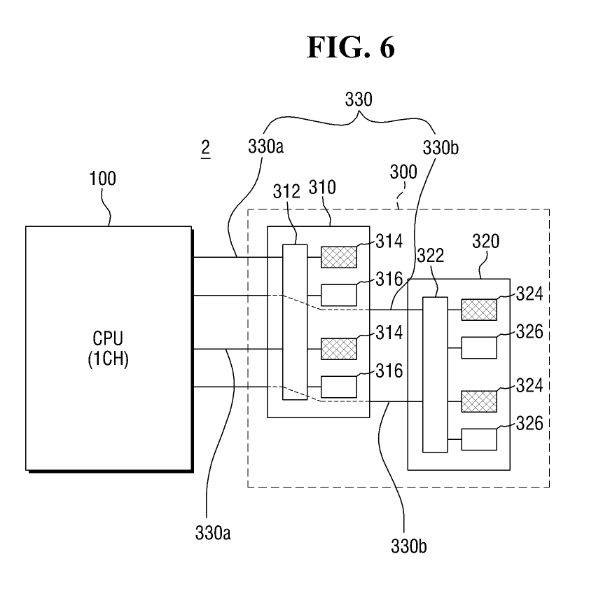

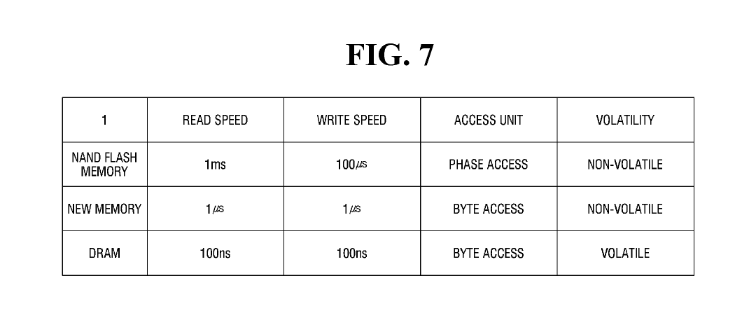

A hybrid DIMM structure according to a second embodiment of the present inventive concept will now be described in detail with reference to FIGS. 6 and 7. For simplicity, a description of elements substantially identical to those of the first embodiment will be simplified or omitted.

FIG. 6 is a block diagram illustrating the internal structure of a hybrid memory module structure, such as a DIMM structure 2 according to a second embodiment of the present inventive concept. Though a DIMM structure is described below, the principles of the embodiments described below may be applied to other types of memory module structures.

Referring to FIG. 6, the hybrid DIMM structure 2 according to the second embodiment includes a CPU 100, a data line 330, and a second memory module structure 300.

The second memory module structure 300 may include a first memory module 310 (e.g., DIMM 310) and a second memory module 320 (e.g., DIMM 320).

The first DIMM 310 may be connected to a first data line 330a and may not be connected to a second data line 330b. That is, the first DIMM 310 may be connected to a part of the data line 330 and may not be connected to the other part of the data line 330.

The first DIMM 310 may include a first memory controller 312, first memories 314, and second memories 316. In one embodiment, the first memories 314 may be a first type of memory, such as volatile memories. For example, the first memories 314 may be, e.g., DRAMs. However, the present inventive concept is not limited thereto, and other volatile memories can be used. In certain embodiments, non-volatile memories, such as magnetic random access memory (MRAM) can be used.

Each of the first memories 314 can operate as the main memory 200, or working memory. Consequently, the first memories 314 of the first DIMM 310 can exchange data with the CPU 100 using the first data line 330a, which is a part of the data line 330.

Each of the first memories 314 may include one or more semiconductor memory devices. For example, each memory 314 may be a semiconductor memory package that includes one or more semiconductor chips. Further, each memory 314 may include a plurality of packages that form a package-on-package device.

In one embodiment, the second memories 316 may be a second type of memory, such as nonvolatile memories. For example, in one embodiment, each of the sixth memories 316 may include at least one of a phase change random access memory (PRAM), a resistance random access memory (RRAM), a nano-floating gate memory (NFGM), a polymer random access memory (PoRAM), a magnetic random access memory (MRAM), and a ferroelectric random access memory (FRAM). However, the present inventive concept is not limited thereto. Each of the second memories 316 may also be a memory that can serve as the main memory 200.

That is, like each of the first memories 314, each of the second memories 316 can operate as the main memory 200. Consequently, the second memories 316 of the first DIMM 310 can exchange data with the CPU 100 using the first data line 330a, which is a part of the data line 330.

Each of the second memories 316 may include one or more semiconductor memory devices. For example, each memory 316 may be a semiconductor memory package that includes one or more semiconductor chips. Further, each memory 316 may include a plurality of packages that form a package-on-package device.

The first memory controller 312 may control data of the first memories 314 and the second memories 316. For example, the first memory controller 312 may receive data from the CPU 100 and classify the received data. In one embodiment, the first memory controller 312 may determine to which of the first and second memories 314 and 316 the received data will be allocated.

The first memories 314 may be relatively faster than the second memories 316. Since the first and second memories 314 and 316 have different processing speeds, data allocated to each of the first and second memories 314 and 316 may be managed. For example, in one embodiment, data that is more desirable to be written to and read from in a shorter period of time can be written to and read from the first memories 314 as opposed to the second memories 316, since the first memories 314 may be faster than the second memories.

The first memory controller 312 may determine to where data should be allocated in various ways. For example, the first memory controller 312 may perform a buffer operation in order to adjust the difference in speed between the CPU 100 and the first memories 314. The first memory controller 312 may also perform a buffer operation in order to adjust the difference in speed between the CPU 100 and the second memories 316.

The first memory controller 312 may perform read and write operations on behalf of the first memories 314 and the second memories 316.

The second DIMM 320 may be connected to the second data line 330b and may not be connected to the first data line 330a, and thus may connect to the channel of the CPU 100 via the second data line 330b. As such, the second DIMM 320 may be connected to a part of the data line 330 and may not be connected to the other part of the data line 330.

The second DIMM 320 may include a second memory controller 322, third memories 324, and fourth memories 326. In one embodiment, the third memories 324 may be a third type of memory, such as volatile memories. The third type of memory may be the same type as the first type of memory in the first DIMM 310. For example, the third memories 324 may be, e.g., DRAMs. However, the present inventive concept is not limited thereto, and other volatile memories, or nonvolatile memories, can be used. The third memories 324 may be of the same type as the first memories 314, or may be different types. The third memories 324 may be in the same category, or type, of memory as the first memories 314 (e.g., nonvolatile), and then may have the same or different types within that category, or sub-types within the type (e.g., both may be DRAM).

Each of the third memories 324 can operate as the main memory 200, or working memory. Consequently, the third memories 324 of the second DIMM 320 can exchange data with the CPU 100 using the second data line 330b, which is a part of the data line 330.

Each of the third memories 324 may include one or more semiconductor memory devices. For example, each memory 314 may be a semiconductor memory package that includes one or more semiconductor chips. Further, each memory 314 may include a plurality of packages that form a package-on-package device.

In one embodiment, the fourth memories 326 may be a fourth type of memory, such as nonvolatile memories. The fourth type of memory may be the same type as the second type of memory in the first DIMM 310. For example, in one embodiment, each of the fourth memories 326 may include at least one of a PRAM, an RRAM, an NFGM, a PoRAM, an MRAM, and an FRAM. However, the present inventive concept is not limited thereto. Each of the fourth memories 326 may also be a memory that can serve as the main memory 200. In one embodiment, the fourth memories 326 may be of the same type as the second memories 316, or may be different types. The fourth memories 326 may be in the same category, or type, of memory as the first memories 316 (e.g., nonvolatile), and then may have the same or different types within that category, or sub-types within the type (e.g., both may be MRAM).

In one embodiment, like each of the third memories 324, each of the fourth memories 326 can operate as the main memory 200. Consequently, the fourth memories 326 of the second DIMM 320 can exchange data with the CPU 100 using the second data line 330b, which is a part of the data line 330.

Each of the fourth memories 326 may include one or more semiconductor memory devices. For example, each memory 326 may be a semiconductor memory package that includes one or more semiconductor chips. Further, each memory 326 may include a plurality of packages that form a package-on-package device.

The second memory controller 322 may control data of the third memories 324 and the fourth memories 326. For example, the second memory controller 322 may receive data from the CPU 100 and classify the received data. In one embodiment, the second memory controller 322 may determine to which of the third and fourth memories 324 and 326 the received data will be allocated.

The third memories 324 may be relatively faster than the fourth memories 326. Since the third and fourth memories 324 and 326 may have different processing speeds, data allocated to each of the third and fourth memories 324 and 326 may be managed.

The second memory controller 322 may determine to where data should be allocated in various ways. The second memory controller 322 may perform a buffer operation in order to adjust the difference in speed between the CPU 100 and the third memories 324. The second memory controller 322 may also perform a buffer operation in order to adjust the difference in speed between the CPU 100 and the fourth memories 326. The second memory controller 322 may perform read and write operations on behalf of the third memories 324 and the fourth memories 326.

As described previously, the first and third memories 314 and 324 may be of the same type. For example, the first and third memories 314 and 324 may be volatile memories. In a more specific example, the first and third memories 314 and 324 may include DRAMs.

As described above, the second and fourth memories 316 and 326 may be of the same type. For example, the second and fourth memories 316 and 326 may be nonvolatile memories. In a more specific example, each of the second and fourth memories 316 and 326 may include at least one of a PRAM, an RRAM, an NFGM, a PoRAM, an MRAM, and an FRAM.

In certain embodiments, the first DIMM 310 and the second DIMM 320 may have the same configuration. However, the first DIMM 310 and the second DIMM 320 may use different parts of the data line 330. For example, the third DIMM 310 may use the third data line 330a, and the fourth DIMM 320 may use the fourth data line 330b.

Unlike in the conventional DIMM structure filling empty slots with two different types of memory modules that share a single data line, in the hybrid DIMM structure 2 according to the second embodiment of the present inventive concept, DIMMs do not share the entire data line 330. Rather, the DIMMs described above use different parts of the data line 330, and the different parts may be dedicated the different respective DIMMs.

As a comparison, in the conventional DIMM structure filling empty slots, the main memory 210′ (see FIG. 3) and the storage device 220′ exist in different DIMMs. Accordingly, the performance of the main memory 210′ is reduced.

On the other hand, in the hybrid DIMM structure 2 according to the second embodiment of the present inventive concept, DIMMs use different parts of the data line 330 instead of sharing the data line 330. Therefore, although two DIMMs are used in the second memory module structure 300, the level of performance that can be obtained when only DIMM is used can be obtained because the two DIMMs use different parts of the data line 330 instead of sharing the data line 330.

For example, if the second memory module structure 300 of one channel consists of eight 8 GB fifth memories 314, all of the eight first memories 314 are included in the third DIMM 310 in the conventional DIMM structure. In the hybrid DIMM structure 2 according to the current embodiment, however, the eight first memories 314 are divided into two groups of four first memories 314, and four first memories 314 are included in each of the first DIMM 310 and the second DIMM 320. Therefore, the total number of the first memories 314 used is the same as in the conventional DIMM structure, and different parts of the data line 330 are used. Accordingly, the performance of the second memory module structure 300 may not be reduced.

In addition, since each of the first DIMM 310 and the second DIMM 320 has an empty space for accommodating eight memories, the second memories 316 can be added to this empty space. Therefore, the empty space can be utilized while the performance of the second memory module structure 300 is maintained by avoiding sharing the data line 330.

Further, since each of the second and fourth memories 316 and 326 additionally use a high-speed DIMM interface, a far greater memory capacity can be obtained. The hybrid DIMM structure 2 according to the second embodiment of the present inventive concept converts data line sharing between DIMMs into data line sharing between heterogeneous memories within a DIMM. This results in a more efficient, faster and larger memory.

FIG. 7 is a table comparing first and second memories of the hybrid DIMM structure 2 according to the second embodiment of the present inventive concept.

Referring to FIG. 7, a new memory refers to a new type of memory compared to the conventional DIMM memories, such as, for example, PRAM, an RRAM, an NFGM, a PoRAM, an MRAM, and an FRAM of each of the second and fourth memories 316 and 326

The new memory requires a shorter time to perform read and write operations than a NAND flash memory. For example, the NAND flash memory may require approximately 1 ms to perform a read operation and approximately 100 μs to perform a write operation, whereas the new memory may require approximately 1 μs to perform a read operation and approximately 1 μs to perform a write operation. In addition, a DRAM relatively faster than the NAND flash memory and the new memory may require approximately 100 ns to perform a read operation and approximately 100 ns to perform a write operation.

By comparing the speeds of the above memories, it can be understood that there is a relatively small difference in speed between the new memory and the DRAM. Therefore, the first and second memories 314 and 316 or the third and fourth memories 326 in the hybrid DIMM structure 2 according to the second embodiment of the present inventive concept have relatively similar speeds. As a result, the hybrid DIMM structure 2 is more efficient than a DIMM structure including the NAND flash memory.

In addition, while the NAND flash memory accesses data on a phase-by-phase basis, the new memory and the DRAM access data on a byte-by-byte basis. Therefore, the new memory and the DRAM have similar access characteristics.

While the DRAM is a volatile memory, the NAND flash and the new memory are nonvolatile memories. However, although the new memory is a nonvolatile memory, it cannot retain data as long as the NAND flash memory. Therefore, it can be understood that the new memory has intermediate characteristics between volatile characteristics and nonvolatile characteristics.

Since the new memory and the DRAM have similar characteristics, even if they are installed in one DIMM, they can be driven relatively efficiently. For example, since the hybrid DIMM structure 2 according to the second embodiment of the present inventive concept includes the similar first and second memories 314 and 316 or the similar third and fourth memories 324 and 326 in one DIMM, it can perform operations more efficiently.

A method of driving the hybrid DIMM structure 1 according to the first embodiment of the present inventive concept will now be described with reference to FIGS. 1, 5 and 8.

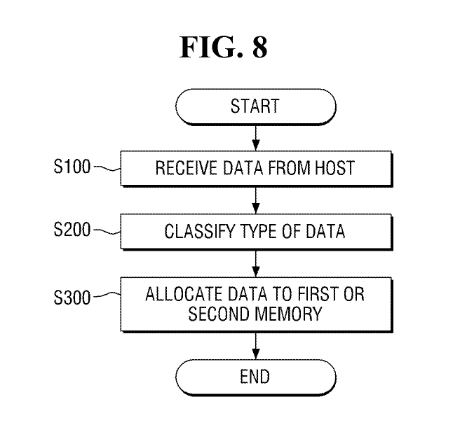

FIG. 8 is a flowchart illustrating an exemplary method of driving the hybrid DIMM structure 1 according to the first exemplary embodiment of the present inventive concept.

Referring to FIG. 8, the hybrid DIMM structure 1 receives data from a host (operation S100).

Specifically, referring to FIGS. 1 and 5, the host may be the CPU 100. The CPU 100 may be a device that interprets commands of a computing device and executes arithmetic and logic operations or data processing. The CPU 100 may include a program counter, an ALU, various registers, a command interpretation unit, a control unit, a timing generation circuit, and other circuit elements.

The CPU 100 may include a single processor core or multiple processor cores in order to process data. In an example, the CPU 100 may include a multi-core such as a dual-core, a quad-core, or a hexa-core. The CPU 100 may further include a cache memory positioned inside or outside the CPU 100.

The hybrid DIMM structure 1 may be part of main memory 200. The hybrid DIMM structure 1 may store data processed by the CPU 100, thus functioning as a storage memory, or may function as a working memory of the CPU 100.

The data may be transmitted through the memory bus 500. The memory bus 500 may be the data line 230. The memory bus 500 may connect the CPU 100 and the main memory 200 The memory bus 500 may serve as a path for data exchange between the CPU 100 and the main memory 200. In the memory bus 500, data may move in both directions. Thus, the memory bus 500 may be a two-way (i.e., bi-directional) bus.

The main memory 200 may include the first memory module 210 (e.g., first DIMM 210). The first DIMM 210 may include the first memory controller 212, the first memories 214, and the second memories 216. The first memories 214 may be a first type of memories, such as, for example, volatile memories. In one embodiment, the first memories 214 may be, e.g., DRAMs. However, the present inventive concept is not limited thereto, and other volatile memories, or nonvolatile memories, can be used.

Each of the first memories 214 can operate as a main memory. Consequently, the first memories 214 of the first DIMM 210 can exchange data with the CPU 100 using the first data line 230a, which is a part of the data line 230.

The second memories 216 may be a second type of memories, such as, for example, nonvolatile memories. For example, each of the second memories 216 may be part of an SSD including a NAND flash memory. However, the present inventive concept is not limited thereto. Each of the second memories 216 may be a memory that can serve as the storage device 600.

In one embodiment, each of the second memories 216 can operate as the storage device 600. Consequently, the second memories 216 of the first DIMM 210 can exchange data with the CPU 100 using the first data line 230a, which is a part of the data line 230.

Referring back to FIG. 8, the type of the received data is classified (operation S200).

Specifically, referring to certain embodiments as discussed in connection with FIGS. 1 and 5, the hybrid DIMM structure 1 may include the volatile first memories 214 and the nonvolatile second memories 216. Therefore, it should be determined to which of the first and second memories 214 and 216 the received data will be allocated. The first memory controller 212 may identify the type of the received data and determine whether the received data will be stored as storage data or as working data, for example, for storing in a storage memory or for storing in a working memory.

Referring back to FIG. 8, the received data is allocated to first or second memories (operation S300).

Since the first memory controller 212 has classified which data should be allocated to which of the first and second memories 214 and 216 in advance, it can allocate each data to the first or second memories 214 and 216 based on the classification.

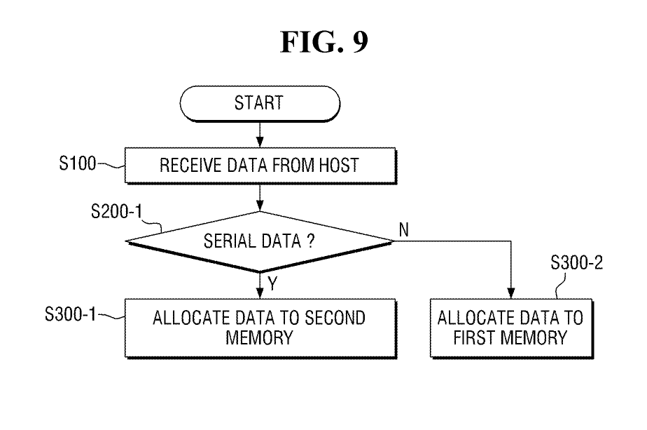

An exemplary method of driving the hybrid DIMM structure 1 according to the first exemplary embodiment of the present inventive concept will now be described in greater detail with reference to FIG. 9.

FIG. 9 is a flowchart illustrating, in greater detail, an exemplary method of driving the hybrid DIMM structure 1 according to the first exemplary embodiment of the present inventive concept. For example, FIG. 9 may indicate the driving method of FIG. 8 in detail.

Referring to FIG. 9, the hybrid DIMM structure 1 receives data from a host (operation S100) and determines whether the received data is serial data (operation S200-1).

The first memory controller 212 may determine to where data should be allocated based on the transmission mode of the data. That is, data received continuously and sequentially (i.e., sequential data) may be stored in the second memories 216. This is because data stored in the second memories 216 may be mass data, also described as storage data, that should be retained even after power supply is interrupted or after an application is closed.

Conversely, data received discontinuously and randomly may be considered as data to be stored temporarily for operations, also described as working data. Therefore, the randomly received data may be transmitted to the first memories 214.

Based on the above classification criterion, the first memory controller 212 may classify data.

Referring back to FIG. 9, the received data is allocated to first or second memories. For example, if the received data is serial data, the first memory controller 212 allocates the received data to the second memories 216 (operation S300-1). If the received data is not the serial data, the first memory controller 212 allocates the received data to the first memories 214 (operation S300-2).

The above method of driving the hybrid DIMM structure 1 according to the first embodiment of the present inventive concept may be efficient when the load on the host is low and data can be automatically managed with a small amount of computation.

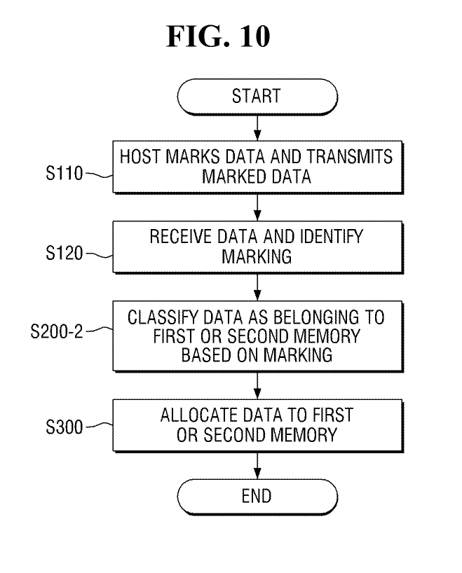

Another exemplary method of driving the hybrid DIMM structure 1 according to the first embodiment of the present inventive concept will now be described in detail with reference to FIG. 10.

FIG. 10 is a flowchart illustrating another exemplary method of driving the hybrid DIMM structure 1 according to the first exemplary embodiment of the present inventive concept.

Referring to FIG. 10, a host marks data and transmits the marked data (operation S110).

Specifically, referring to FIGS. 1 and 5, the host, i.e., the CPU 100 may mark data in advance to indicate whether the data is intended for a working memory (e.g., the main memory 200) or a storage memory (e.g., the storage device 600) and transmit the data to the hybrid DIMM structure 1.

Referring back to FIG. 10, the data is received, and the marking of the data is identified (operation S120).

Specifically, referring to FIGS. 1 and 5, since the data has been marked in advance, the first memory controller 212 can determine whether the data should be allocated to the first memories 214 or the second memories 216 based on the marking of the data.

Referring back to FIG. 10, the data is classified as belonging to first or second memories based on the marking (operation S200-2).

Since the first memory controller 212 classifies the data based on the marking, the amount of computation required of the first memory controller 212 is very small. Therefore, a data classification operation can be performed at high speed by reducing the amount of computation required of the first memory controller 212 of the hybrid memory module using the relatively fast CPU 100.

Referring back to FIG. 10, the data is allocated to the first or second memories (operation S300).

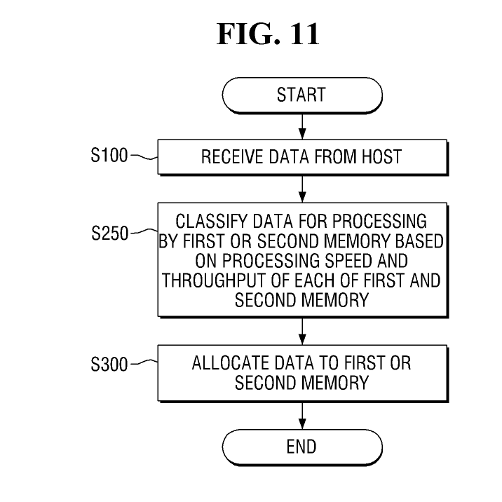

An exemplary method of driving the hybrid DIMM structure 2 according to the second exemplary embodiment described above will now be described in detail with reference to FIGS. 6 and 11. For simplicity, a description of elements and features substantially identical to those of the method of driving the hybrid DIMM structure 1 according to the first embodiment will be simplified or omitted.

FIG. 11 is a flowchart illustrating an exemplary method of driving the hybrid DIMM structure 2 according to the second exemplary embodiment of the present inventive concept.

Referring to FIG. 11, data is received from a host (operation S100), and the received data is classified for processing (e.g., reading or writing) by first or second memories based on the processing speed and throughput of each of the first and second memories (operation S200). For example, the latency of read and write accesses of the first and second memories may be different, and the number of bits accessible in a certain period of time may also be different. Therefore, the first and second memory controllers 312 and 322 may perform the classification such that the read and write processing with the different memories on each hybrid memory module may then take place.

Specifically, referring to FIG. 6, the host is the CPU 100, and the hybrid DIMM structure 2 according to the second embodiment of the present inventive concept is located inside the second memory module 300. The second memory module 300 includes the first DIMM 310.

The third DIMM 310 may include the third controller 312, the first memories 314, and the second memories 316. The first memories 314 may be a first type of memories, such as volatile memories. For example, the first memories 314 may be, e.g., DRAMs. However, the present inventive concept is not limited thereto, and other volatile memories can be used.

Each of the first memories 314 can operate as the main memory 200. Consequently, the first memories 314 of the first DIMM 310 can exchange data with the CPU 100 using the first data line 330a which is a part of the data line 330.

The second memories 316 may be a second type of memories, such as nonvolatile memories. For example, each of the second memories 316 may include at least one of a PRAM, an RRAM, an NFGM, a PoRAM, an MRAM, and an FRAM. However, the present inventive concept is not limited thereto. Each of the second memories 316 may also be a memory that can serve as the main memory 200.

As such, like each of the first memories 314, each of the second memories 316 can operate as the main memory 200. Consequently, the second memories 316 of the first DIMM 310 can exchange data with the CPU 100 using the first data line 330a, which is a part of the data line 330.

The first memory controller 312 may control data of the first memories 314 and the second memories 316. For example, the first memory controller 312 may receive data from the CPU 100 and classify the received data. In one embodiment, the first memory controller 312 may determine to which of the first and second memories 314 and 316 the received data will be allocated.

The first memories 314 may be relatively faster than the second memories 316. Since the first and second memories 314 and 316 have different processing speeds, data allocated to each of the first and second memories 314 and 316 may be managed.

Referring back to FIG. 11, the data is allocated to the first or second memories (operation S300).

The first memory controller 312 may allocate the data based on the result of data classification.

The above method of driving the hybrid DIMM structure 2 according to the second embodiment of the present inventive concept utilizes an empty slot of a DIMM structure as well as an additional DIMM compared with a conventional method. Therefore, a reduction in the performance of the main memory 200 can be prevented or reduced. Further, since a new type of memory is added to a DIMM-type structure, a working memory with a large capacity and high efficiency can be secured.

While the present disclosure has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A hybrid memory module structure comprising:
a channel for receiving data from and transmitting data to a device external to the hybrid memory module structure;
a first memory module connected to the channel, the first memory module including at least a first memory and a second memory, the first memory being a working memory and the second memory being a storage memory;
a second memory module connected to the channel, the second memory module including at least a third memory and a fourth memory, the third memory being a working memory and the fourth memory being a storage memory,
wherein the channel includes a first data line commonly connected to the first memory and the second memory, and
wherein the channel includes a second data line commonly connected to the third memory and the fourth memory.

2. The hybrid memory module structure of claim 1, wherein:
the first memory and third memory are the same type of memory; and
the second memory and fourth memory are the same type of memory.

3. The hybrid memory module structure of claim 2, wherein:
the first memory and third memory are volatile memories; and
the second memory and fourth memory are nonvolatile memories.

4. The hybrid memory module structure of claim 3, wherein:
the first memory and third memory are dynamic random access memories (DRAMs); and
the second memory and fourth memory are one of: flash memory, phase change random access memory (PRAM), resistance random access memory (RRAM), nano-floating gate memory (NFGM), polymer random access memory (PoRAM), magnetic random access memory (MRAM), and ferroelectric random access memory (FRAM).

5. The hybrid memory module structure of claim 1, wherein:
the first data line is not connected to the third or fourth memories, and
the second data line is not connected to the first or second memories.

6. The hybrid memory module structure of claim 5, wherein the first memory module further comprises a controller which allocates serial data received from a host through the first data line to the second memory and allocates non-serial data to the first memory.

7. The hybrid memory module structure of claim 1, wherein the first memory module further comprises a controller configured to classify data received from a host through the first data line and perform read and write operations on behalf of the first and second memories.

8. The hybrid memory module structure of claim 7, wherein the controller is configured to classify the data based on a marking of the data made by the host, or based on a transmission mode of the data.

9. The hybrid memory module structure of claim 1, wherein:
each memory of the first memory module includes one or more semiconductor chips; and
each memory of the second memory module includes one or more semiconductor chips.

10. The hybrid memory module structure of claim 9, wherein:
the first memory module is a dual inline memory module including at least four memories that include the first memory and second memory; and
the second memory module is a dual inline memory module including at least four memories that include the third memory and fourth memory.

11. The hybrid memory module structure of claim 1, wherein read and write operations of the first memory are faster than those of the second memory.

12. The hybrid memory module structure of claim 1, wherein the channel includes two slots, a first for connecting the first memory module, and a second for connecting the second memory module.

13. The hybrid memory module structure of claim 2, further comprising:
a first memory controller on the first hybrid memory module, the first memory controller configured to receive data from the first data line and to determine which of the first or second memories in which to store the received data; and
a second memory controller on the second hybrid memory module, the second memory controller configured to receive data from the second data line and to determine which of the third or fourth memories in which to store the received data.

14. A hybrid memory module structure comprising:
a channel for receiving data from and transmitting data to a device external to the hybrid memory module;
a first hybrid memory module connected to the channel, the first hybrid memory module including at least a first memory and a second memory, the first memory being a different type of memory from the second memory
a second hybrid memory module connected to the channel, the second memory module including at least a third memory and a fourth memory, the third memory being a different type of memory from the fourth memory;
a first memory controller on the first hybrid memory module, the first memory controller configured to receive data from the channel and to determine which of the first or second memories in which to store the received data; and
a second memory controller on the second hybrid memory module, the second memory controller configured to receive data from the channel and to determine which of the third or fourth memories in which to store the received data.

15. The hybrid memory module structure of claim 14, further comprising:
a first data line of the channel commonly connected to the first memory and the second memory through the first memory controller; and
a second data line of the channel commonly connected to the third memory and the fourth memory through the second memory controller.

16. An electronic device, comprising:
a first memory controller;
a first data line connected to the first memory controller and for communicating with an external host; and
a first hybrid memory module connected to the first memory controller, the first hybrid memory module including at least a first memory and a second memory, the first memory being a first type of memory and the second memory being a second type of memory,
wherein the first memory controller is configured to determine whether data received from the host is to be allocated to the first memory or the second memory.

17. The electronic device of claim 16, wherein the first type of memory is a working memory and the second type of memory is a storage memory.

18. The electronic device of claim 16, wherein the first memory controller is configured to classify the data based on a marking of the data made by the host, or based on a transmission mode of the data, in order to make the determination.

19. The electronic device of claim 16, further comprising:
a second memory controller;
a second data line connected to the second memory controller and for communicating with the external host; and
a second hybrid memory module connected to the second memory controller, the second hybrid memory module including at least a first memory and a second memory, the first memory of the second hybrid memory module being the first type of memory and the second memory of the second hybrid memory module being the second type of memory,
wherein the second memory controller is configured to determine whether data received from the host is to be allocated to the first memory of the second hybrid memory module or the second memory of the second hybrid memory module.

20. The electronic device of claim 19, wherein the first data line and the second data line are part of a single channel connected to the first hybrid memory module and the second hybrid memory module.
